(19) United States
(12) Patent Application Publication
(10) Pub. No.: US 2024/0363572 A1
(43) Pub. Date: Oct. 31, 2024

(54) SEMICONDUCTOR DEVICE

(71) Applicant: ROHM CO., LTD., Kyoto-shi (JP)

(72) Inventor: Akinori NII, Kyoto-shi (JP)

(21) Appl. No.: 18/771,523

(22) Filed: Jul. 12, 2024

Related U.S. Application Data
(63) Continuation of application No. PCT/JP2022/047329, filed on Dec. 22, 2022.

(30) Foreign Application Priority Data
Jan. 14, 2022 (JP) 2022-004243

(51) Int. Cl. H01L 23/00

(52) U.S. Cl. CPC H01L 24/13; H01L 24/05; H01L 24/06; H01L 24/14; H01L 24/16; H01L 2224/05015; H01L 2224/05073; H01L 2224/05155; H01L 2224/05582; H01L 2224/05644; H01L 2224/05664; H01L 2224/06051; H01L 2224/13083; H01L 2224/13147; H01L 2224/1357; H01L 2224/1403; H01L 2224/16245; H01L 2924/384

(57) ABSTRACT

A semiconductor device includes a semiconductor element, conductive member connected to the semiconductor element, first metal layer and second metal layer. The semiconductor element includes element obverse/reverse surfaces opposite from each other in thickness direction, and first/second electrode terminals on the element obverse surface. The first metal layer is on the conductive member and bonded to the first electrode terminal. The second metal layer is on the conductive member and bonded to the second electrode terminal. The first electrode terminal includes a first bonding surface facing the first metal layer. The second electrode terminal includes a second bonding surface facing the second metal layer. The first bonding surface is smaller in area than the second bonding surface. The difference between representative lengths of the first metal layer and the first bonding surface is smaller than the difference between representative lengths of the second metal layer and the second bonding surface.

### TECHNICAL FIELD

The present disclosure relates to semiconductor devices.

### BACKGROUND ART

A semiconductor device including a semiconductor element that is flip-chip bonded to a plurality of leads has been proposed. Such a semiconductor device is disclosed in JP-A-2020-77694, for example. The semiconductor device includes a plurality of leads, a semiconductor element, a bonding layer, and a sealing resin. The semiconductor element is mounted on the leads, with a first electrodes facing toward the leads. Each first electrode includes a cylindrical pillar portion protruding toward a lead. Each pillar portion is bonded to the lead via a bonding layer. The bonding layers are deposited onto the pillar portions through electroplating, and are subsequently melted and solidified to join the pillar portions and the leads.

The volume of the bonding layer on each pillar portion differs depending on the diameter of the corresponding pillar portion. Thus, depending on the extent to which each bonding layer spreads in the bonding process, the thicknesses of the respective bonding layers may vary. For instance, when a first bonding layer formed on a pillar portion with a smaller diameter and a second bonding layer formed on a pillar portion with a greater diameter spread to the same extent in the bonding process, the second bonding layer with a greater volume becomes thicker than the first bonding layer. Variations in the thicknesses of the bonding layers may result in tilting of the semiconductor element bonded to the leads. The semiconductor element that is tilted relative to the leads may lead to connection failure or other problems.

### BRIEF DESCRIPTION OF THE DRAWINGS

FIG. 1 is a perspective view of a semiconductor device according to a first embodiment of the present disclosure.

FIG. 2 is a plan view of the semiconductor device shown in FIG. 1, with a sealing resin shown as transparent.

FIG. 3 is a plan view of the semiconductor device shown in FIG. 1, with a semiconductor element also shown as transparent.

FIG. 4 is a bottom view of the semiconductor device shown in FIG. 1.

FIG. 5 is a plan view of the semiconductor element.

FIG. 6 is a front view of the semiconductor device shown in FIG. 1.

FIG. 7 is a rear view of the semiconductor device shown in FIG. 1.

FIG. 8 is a right-side view of the semiconductor device shown in FIG. 1.

FIG. 9 is a left-side view of the semiconductor device shown in FIG. 1.

FIG. 10 is a sectional view taken along line X-X in FIG. 3.

FIG. 11 is a sectional view taken along line XI-XI in FIG. 3.

FIG. 12 is a sectional view taken along line XII-XII in FIG. 3.

FIG. 13 is a sectional view taken along line XIII-XIII in FIG. 3.

FIG. 14 is a partially enlarged view of FIG. 10.

FIG. 15 is a partially enlarged view of FIG. 10.

FIG. 16 is a schematic illustration of a method of flip-chip bonding a semiconductor element onto a conductive member.

FIG. 17 is a schematic illustration of a method of flip-chip bonding a semiconductor element onto a conductive member.

FIG. 18 is a schematic illustration of the method of flip-chip bonding a semiconductor element onto a conductive member.

FIG. 19 is a view for comparison with FIG. 18.

FIG. 20 is a view for comparison with FIG. 18.

FIG. 21 is a plan view of a semiconductor device according to a second embodiment of the present disclosure, with a sealing resin and a semiconductor element shown as transparent.

FIG. 22 is a partially enlarged sectional view of the semiconductor device shown in FIG. 21.

FIG. 23 is a partially enlarged sectional view taken along line XXIII-XXIII in FIG. 22.

FIG. 24 is a plan view of a portion of a semiconductor device according to a third embodiment of the present disclosure, with a sealing resin and a semiconductor element shown as transparent.

### DETAILED DESCRIPTION OF EMBODIMENTS

The following describes preferred embodiments of the present disclosure in detail with reference to the drawings.

### First Embodiment

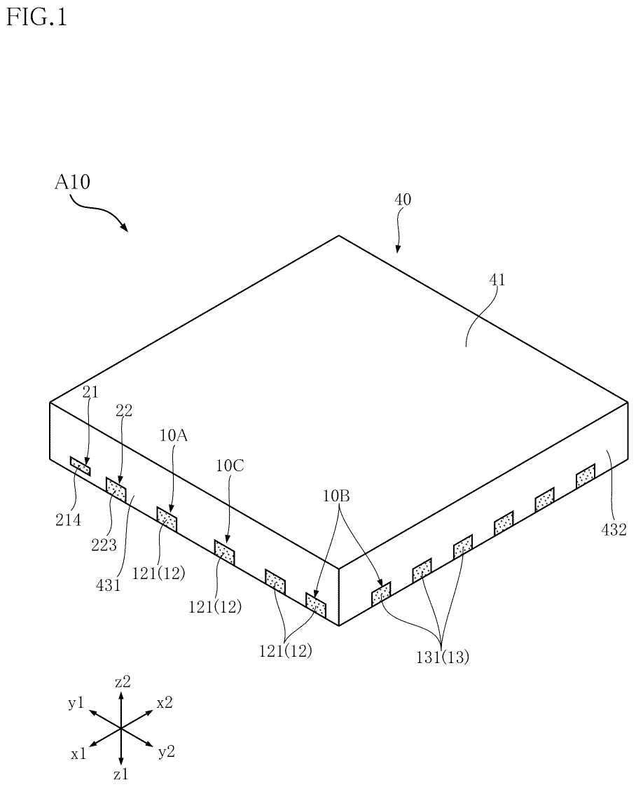

FIGS. 1 to 15 show an example of a semiconductor device according to the present disclosure. The semiconductor device A10 of the present embodiment includes first leads 10A, 10B, and 10C, a plurality of second leads 21, a pair of third leads 22, a plurality of bonding portions 5, a plurality of metal layers 6, a semiconductor element 30, and a sealing resin 40. The package type of the semiconductor device A10 is not limited, which in this embodiment is a quad flat non-leaded (QFN) package as shown in FIG. 1. Additionally, the application or function of the semiconductor device A10 is not specifically limited. The semiconductor device A10 can be used in electronic devices, general industrial devices, vehicle-mounted devices, for example. The semiconductor device A10 can be used as a DC/DC converter or an AC/DC converter, for example. The present embodiment is directed to the semiconductor device A10 configured as a vehicle-mount DC/DC converter.

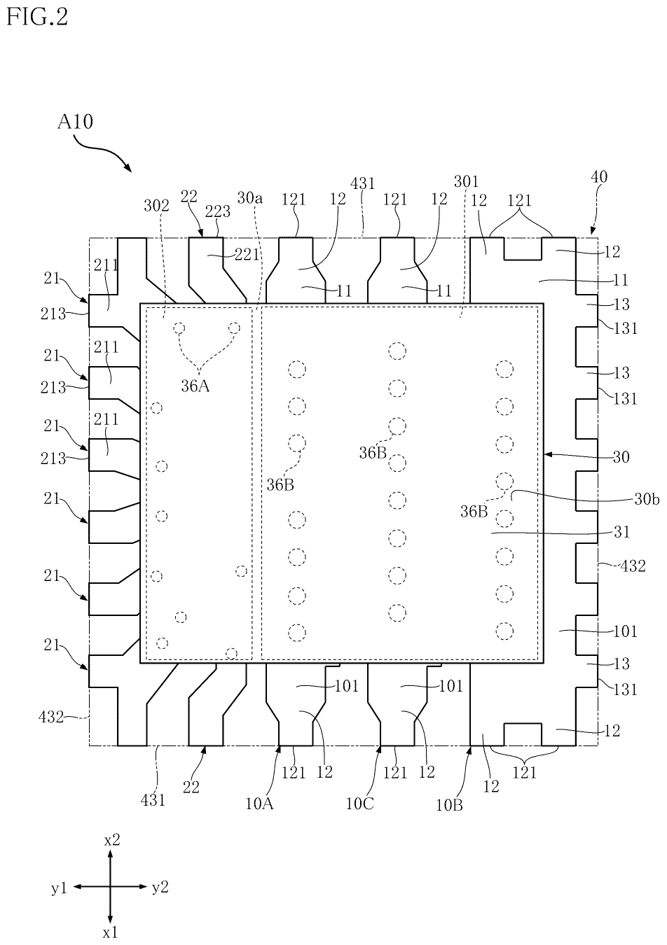

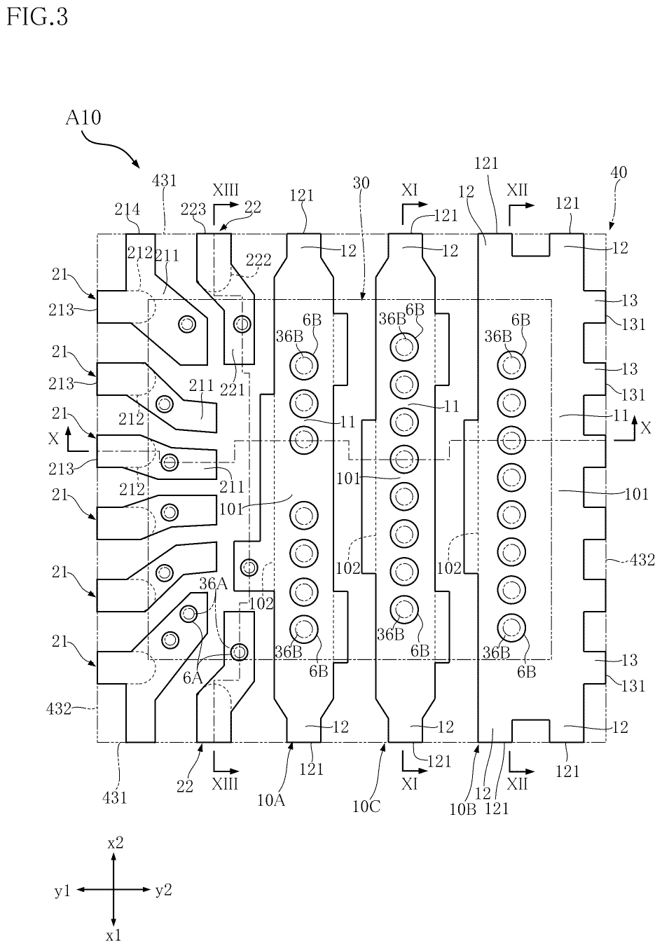

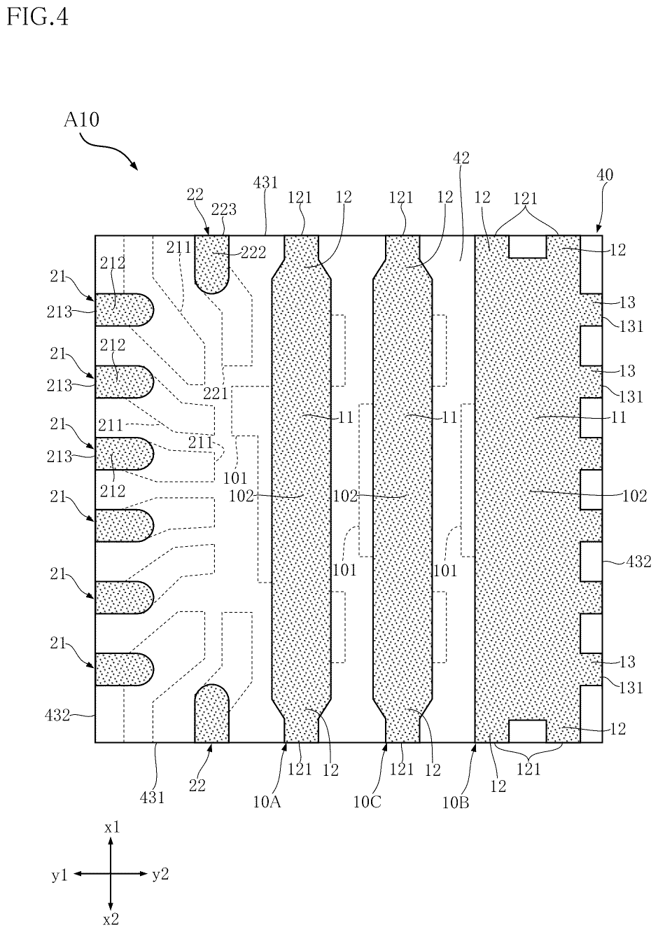

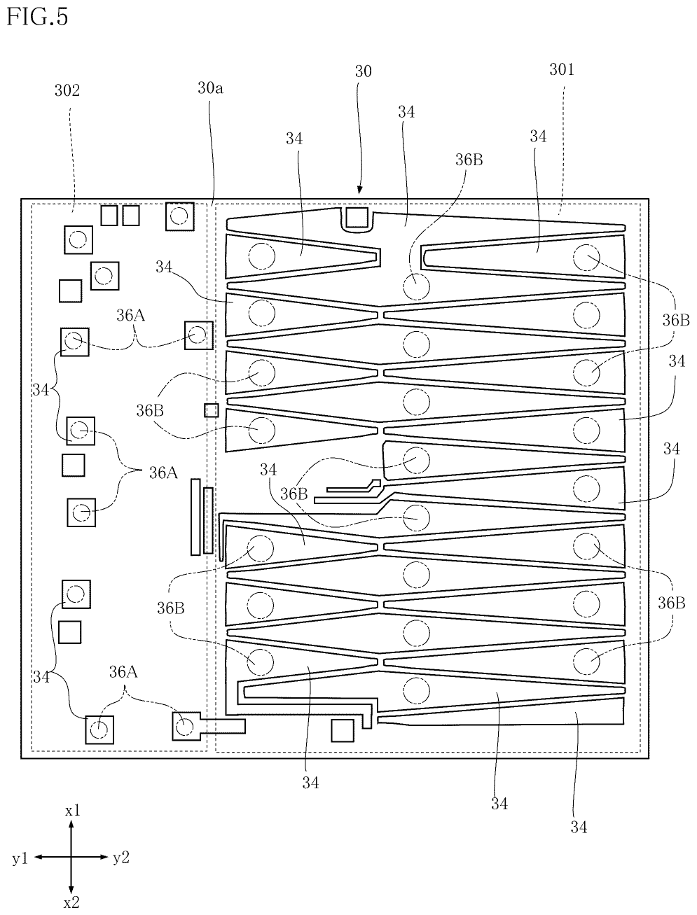

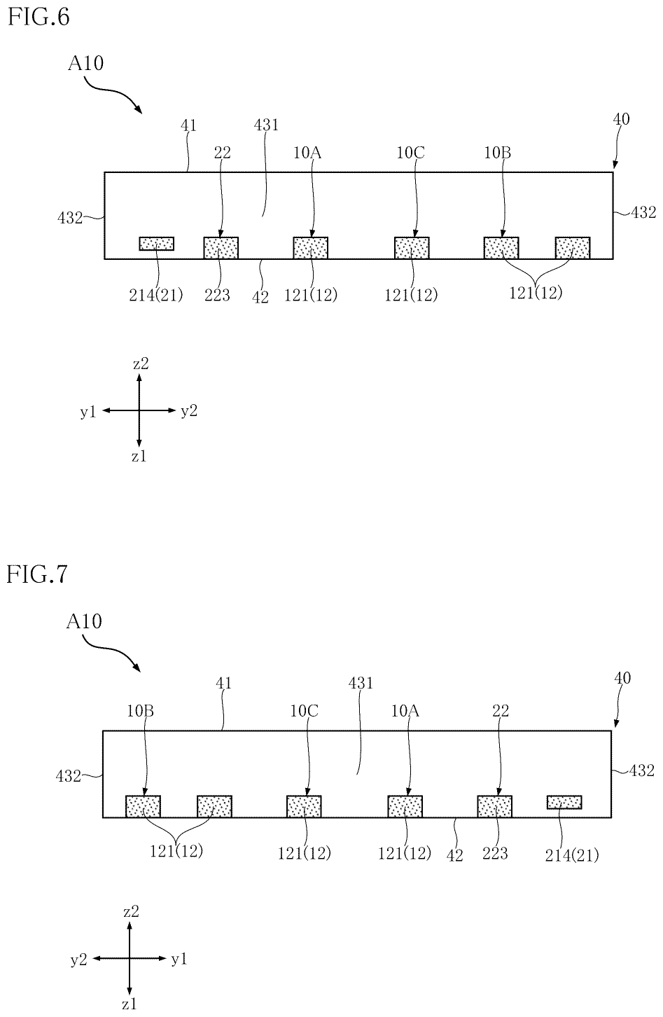

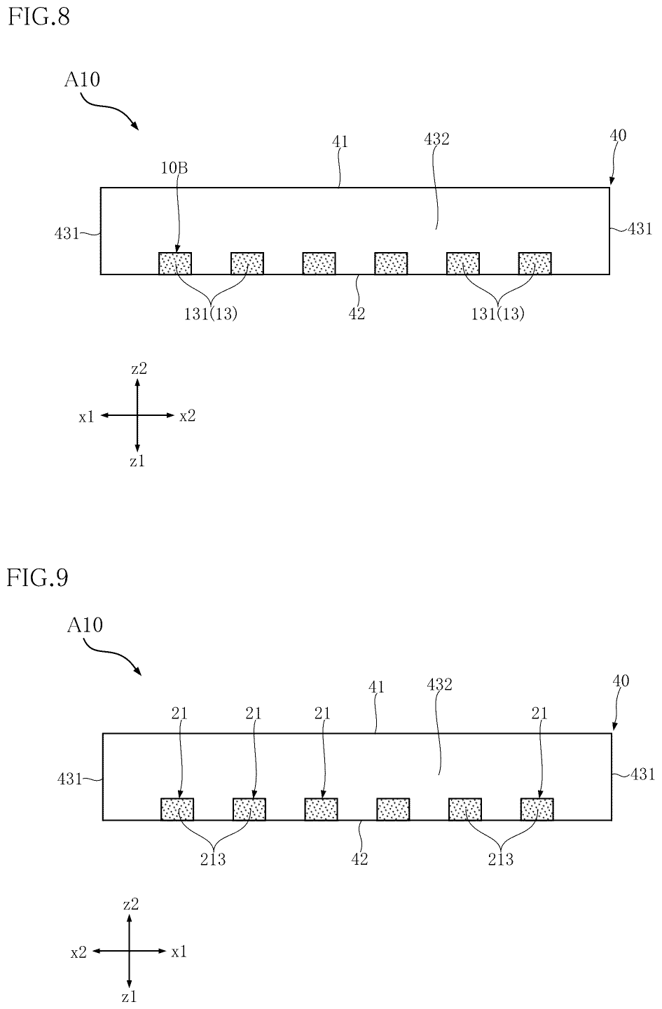

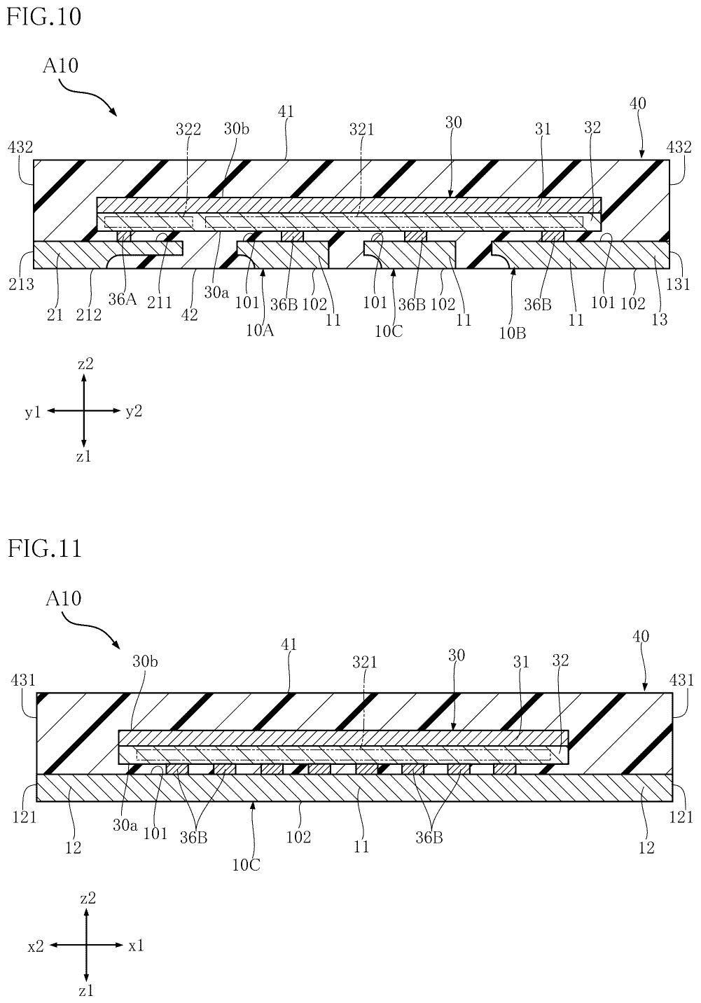

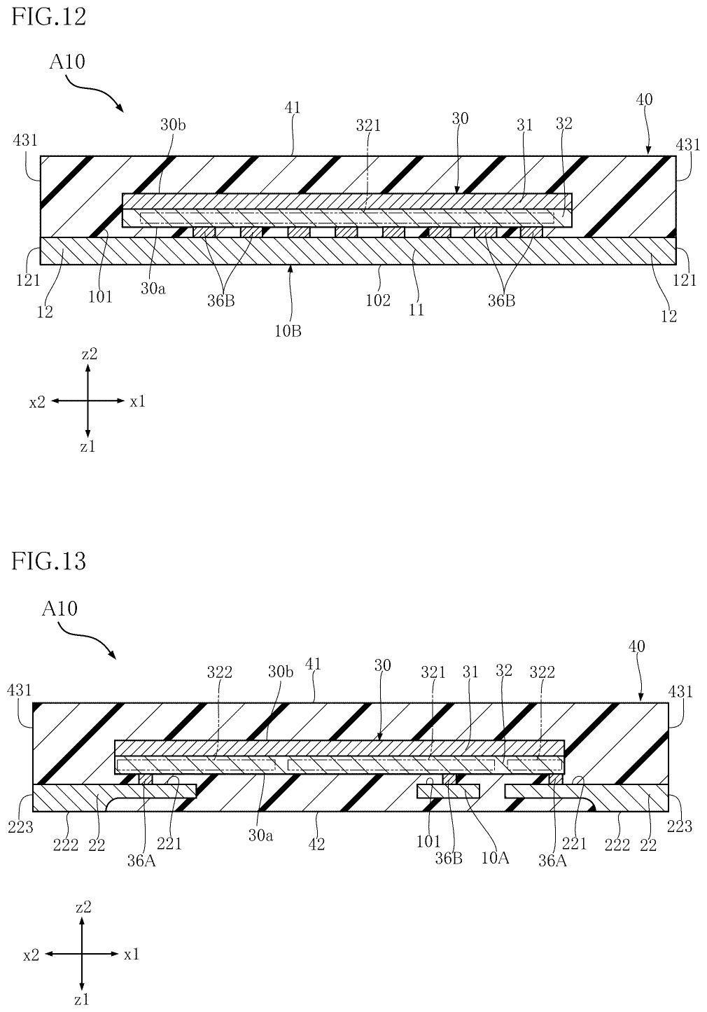

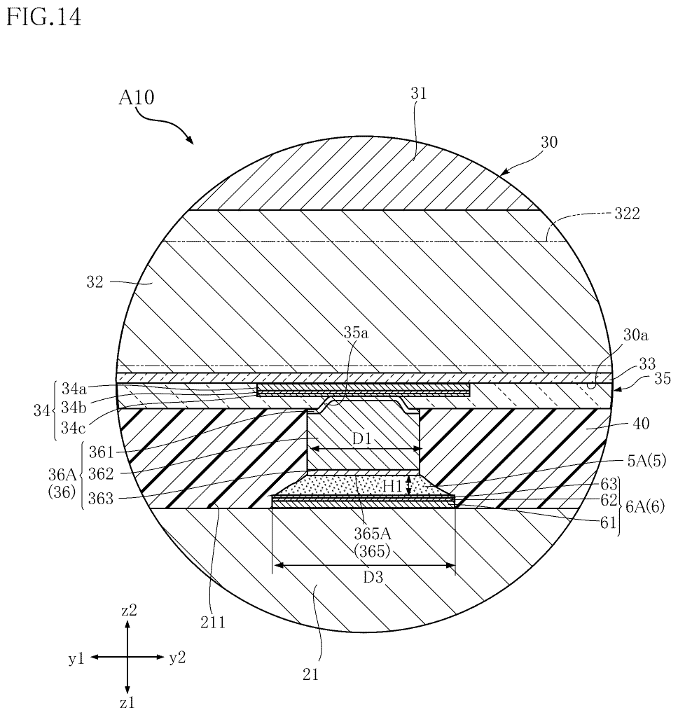

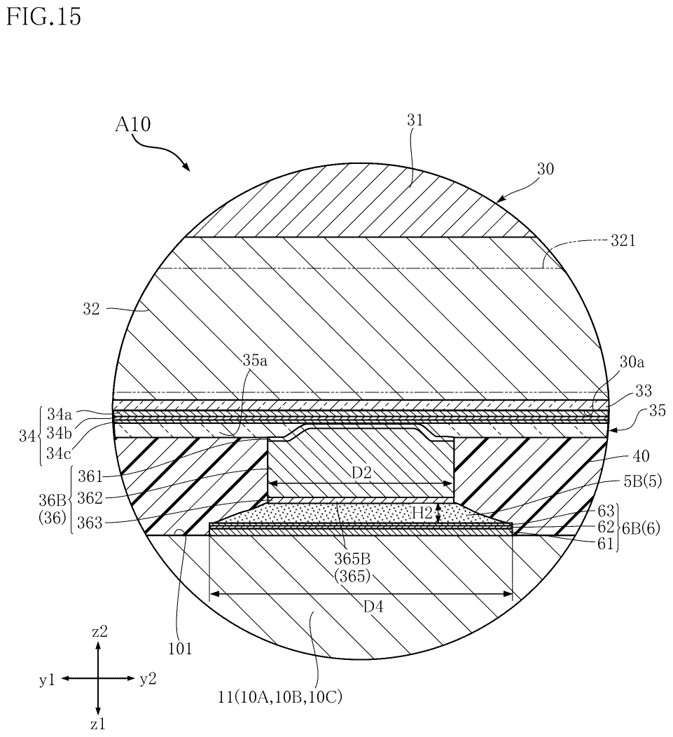

FIG. 1 is a perspective view of the semiconductor device A10. FIG. 2 is a plan view of the semiconductor device A10. For the convenience of description, FIG. 2 shows the sealing resin 40 as transparent, with its outline indicated by an imaginary line (a two-dot-dash line). FIG. 3 is a plan view of the semiconductor device A10. For the convenience of description, FIG. 3 shows the sealing resin 40 and the semiconductor element 30 as transparent, with their outlines indicated by imaginary lines (two-dot-dash lines). FIG. 4 is a bottom view of the semiconductor device A10. FIG. 5 is a plan view of the semiconductor element 30. FIG. 5 shows an insulating layer 35 and a plurality of electrode terminals 36, which will be described later, as transparent, and the outlines of the electrode terminals 36 are indicated by imaginary lines (two-dot-dash lines). FIG. 6 is a front view of the semiconductor device A10. FIG. 7 is a rear view of the semiconductor device A10. FIG. 8 is a right-side view of the semiconductor device A10. FIG. 9 is a left-side view of the semiconductor device A10. FIG. 10 is a sectional view taken along line X-X in FIG. 3. FIG. 11 is a sectional view taken along line XI-XI in FIG. 3. FIG. 12 is a sectional view taken along line XII-XII in FIG. 3. FIG. 13 is a sectional view taken along line XIII-XIII in FIG. 3. FIG. 14 is a partially enlarged view of FIG. 10 (showing a portion around an electrode terminal 36A, which will be described later). FIG. 15 is a partially enlarged view of FIG. 10 (showing a portion around an electrode terminal 36B, which will be described later).

The semiconductor device A10 has the shape of a plate and is rectangular as viewed in the thickness direction (in plan view). For the convenience of description, the thickness direction of the semiconductor device A10 is defined as the z direction, and a direction orthogonal to the z direction along one edge of the semiconductor device A10 (the vertical direction in FIGS. 2 to 4) is defined as the x direction, and the direction orthogonal to the z and x directions (the horizontal direction in FIGS. 2 to 4) is defined as the y direction. The z direction is an example of the “thickness direction”, and the y direction is an example of the “first direction”. The shape and dimensions of the semiconductor device A10 are not particularly limited.

As shown in FIG. 2. the first leads 10A, 10B, and 10C, the second leads 21, and the third leads 22 support the semiconductor element 30 and serve as terminals used for mounting the semiconductor device A10 onto a wiring substrate. As shown in FIGS. 10 to 13, the first leads 10A, 10B, and 10C, the second leads 21, and the third leads 22 each have a portion covered with the sealing resin 40. In FIGS. 1, 4, and 6 to 9, the areas shaded with dots represent the portions of the first leads 10A, 10B, and 10C, the second leads 21, and the third leads 22 that are exposed from the sealing resin 40. In the following description, the first leads 10A, 10B, and 10C, the second leads 21, and the third leads 22 may be collectively referred to as a conductive member 1.

The conductive member 1 is formed by etching a metal plate. The conductive member 1 may be formed by applying other processes to a metal plate, such as punching and bending. The first leads 10A, 10B, and 10C, the second leads 21, and the third leads 22 are spaced apart from each other. The conductive member 1 may be made of, but not limited to, Cu or a Cu alloy.

As shown in FIGS. 3 and 4, each of the first leads 10A, 10B, and 10C is shaped like a strip extending in the x direction as viewed in the z direction. Each of the first leads 10A, 10B, and 10C has a first obverse surface 101 and a first reverse surface 102 facing away from each other in the z direction. The first obverse surface 101 is oriented toward the z2 side in the z direction, facing the semiconductor element 30. The first obverse surface 101 is covered with the sealing resin 40. The first reverse surface 102 is oriented toward the z1 side in the z direction. The first reverse surface 102 is exposed from the sealing resin 40. The first leads 10A, 10B, and 10C support the semiconductor element 30 on their first obverse surfaces 101. In the example shown in FIGS. 3 and 4, for each of the first leads 10A, 10B, and 10C, the first obverse surface 101 is greater in area than the first reverse surface 102. The portion of each of the first leads 10A, 10B, and 10C where the first obverse surface 101 does not overlap with the first reverse surface 102 as viewed in the z direction, may be formed by half-etching the first reverse surface 102, for example. These portions produce anchoring effect, which helps to prevent detachment of the first leads 10A, 10B, and 10C from the bottom surface 42 of the sealing resin 40.

The first leads 10A and 10B receive DC power (voltage) to be converted by the semiconductor device A10. In the present embodiment, the first lead 10A is a positive electrode (P terminal), and the first lead 10B is a negative electrode (N terminal). The first lead 10C outputs AC power (voltage) as converted by a later-described switching circuit 321 of the semiconductor element 30. As shown in FIG. 3, the first leads 10A, 10B, and 10C are arranged in the order of the first lead 10A, the first lead 10C, and the first lead 10B from the y1 side to the y2 side in the y direction. The first lead 10A is located between the second leads 21 and the first lead 10C in the y direction. The first lead 10C is located between the first lead 10a and the first lead 10B in the y direction.

As shown in FIGS. 3 and 4, each of the first leads 10A and 10C has a main section 11 and a pair of side sections 12. The main section 11 extends in the x direction. The pair of side sections 12 are connected to the opposite ends of the main section 11 in the x direction and are narrower in the y direction than the main section 11. Each side section 12 has a first end surface 121. As shown in FIG. 11, the first end surface 121 is connected to the first obverse surface 101 and the first reverse surface 102 and faces in the x direction. The first end surface 121 is exposed from the sealing resin 40.

As shown in FIGS. 3 and 4, the first lead 10B includes a main section 11, four side sections 12, and a plurality of projections 13. The main section 11 extends in the x direction. Two of the side sections 12 are connected to the end of the main section 11 located on the x1 side in the x direction. The other two side sections 12 are connected to the end of the main section 11 located on the x2 side in the x direction. Each of the four side sections 12 has a first end surface 121. As shown in FIG. 12, the first end surface 121 is connected to the first obverse surface 101 and the first reverse surface 102 and faces in the x direction. The first end surface 121 is exposed from the sealing resin 40. Each projection 13 protrudes from the y2 side of the main section 11 in the y direction. Each space between two adjacent projections 13 is filled with the sealing resin 40. Each projection 13 has a sub-end surface 131. As shown in FIG. 10, each sub-end surface 131 is connected to the first obverse surface 101 and the first reverse surface 102 and faces the y2 side in the y direction. The sub-end surface 131 is exposed from the sealing resin 40. As shown in FIG. 8, the sub-end surfaces 131 are arranged at predetermined spaced intervals in the x direction. Note, however, that the first leads 10A, 10B, and 10C are not limited to such a shape having the main section 11 and the side sections 12.

The first reverse surfaces 102, the first end surfaces 121, and the sub-end surfaces 131 of the first leads 10A, 10B, and 10C, which are exposed from the sealing resin 40, may be plated with Sn, for example. Instead of the Sn plating, a plurality of metal layers may be deposited in the order of Ni, Pd, and Au.

As shown in FIG. 3, the second leads 21 are located on the y1 side in the y direction relative to the first lead 10A. One of the second leads 21 is a ground terminal of a later-described control circuit 322 of the semiconductor element 30. The other second leads 21 receive electric power (voltage) to drive the control circuit 322 and electric signals directed to the control circuit 322. As shown in FIGS. 3 and 4, each second lead 21 has a second obverse surface 211, a second reverse surface 212, and a second end surface 213. The shapes of the second leads 21 are not limited.

Each second obverse surface 211 is oriented toward the same side as the first obverse surfaces 101 of the first leads 10A, 10B, and 10C in the z direction, facing the semiconductor element 30. The second obverse surfaces 211 are covered with the sealing resin 40. The semiconductor element 30 are placed on the second obverse surfaces 211. Each second reverse surface 212 faces away from the second obverse surface 211. The second reverse surfaces 212 are exposed from the sealing resin 40. Each second end surface 213 is connected to the second obverse surface 211 and the second reverse surface 212 and faces the y1 side in the y direction. The second end surfaces 213 are exposed from the sealing resin 40. As shown in FIG. 9, the second end surfaces 213 are arranged at predetermined spaced intervals in the x direction. Two of the second leads 21 are located at the ends in the x direction, and each of the two leads additionally has a fourth end surface 214 facing in the x direction. The fourth end surface 214 faces in the x direction and is exposed from the sealing resin 40. In the example shown in FIGS. 3 and 4, for each second lead 21, the second obverse surface 211 is greater in area than the second reverse surface 212. The portion of each second lead 21 where the second obverse surface 211 does not overlap with the second reverse surface 212 as viewed in the z direction, may be formed by half-etching the second reverse surface 212, for example. These portions produce anchoring effect, which helps to prevent detachment of the second leads 21 from the bottom surface 42 of the sealing resin 40.

The second reverse surface 212, the second end surface 213, and the fourth end surface 214 of each second lead 21, which are exposed from the sealing resin 40, may be plated with Sn, for example. Instead of the Sn plating, a plurality of metal layers may be deposited in the order of Ni, Pd, and Au.

As shown in FIG. 3, the pair of third leads 22 are located between the first lead 10A and the plurality of second leads 21 in the y direction. The third leads 22 are spaced apart from each other in the x direction. Each third lead 22 receives inputs, such as an electric signal directed to the control circuit 322 formed in the semiconductor element 30. As shown in FIGS. 3 and 4, each third lead 22 has a third obverse surface 221, a third reverse surface 222, and a third end surface 223. The shapes of the third leads 22 are not limited.

Each third obverse surface 221 is oriented toward the same side as the first obverse surfaces 101 of the first leads 10A, 10B, and 10C in the z direction, facing the semiconductor element 30. The third obverse surfaces 221 are covered with the sealing resin 40. The semiconductor element 30 is placed on the third obverse surfaces 221. The third reverse surface 222 of each third lead 22 faces away from the third obverse surface 221. The third reverse surfaces 222 are exposed from the sealing resin 40. Each third end surface 223 is connected to the third obverse surface 221 and the third reverse surface 222 and faces in the x direction. The third end surfaces 223 are exposed from the sealing resin 40. Each third end surface 223 is aligned with the first end surfaces 121 of the first leads 10A, 10B, and 10C in the y direction. In the illustrated example, for each third lead 22, the third obverse surface 221 is greater in area than the third reverse surface 222. The portions of each third lead 22 where the third obverse surface 221 does not overlap with the third reverse surface 222 as viewed in the z direction, may be formed by half-etching the third reverse surface 222, for example. These portions produce anchoring effect, which helps to prevent detachment of the third leads 22 from the bottom surface 42 of the sealing resin 40.

The third reverse surface 222 and the third end surface 223 of each third lead 22, which are exposed from the sealing resin 40, may be plated with Sn, for example. Instead of the Sn plating, a plurality of metal layers may be deposited in the order of Ni, Pd, and Au.

The first leads 10A, 10B, and 10C, the second leads 21, and the third leads 22 may have recesses that are recessed from their obverse surfaces 101, 211, and 221 in the z direction. The recesses may be formed by half-etching the obverse surfaces 101, 211, and 221. The inner surfaces of the recesses make intimate contact with the sealing resin 40, thereby enhancing the adhesion between each lead and the sealing resin 40. The recesses can also be used to position the semiconductor element 30 as viewed in the z direction (a specific location on the xy plane). The numbers, shapes, and arrangements of the first leads 10A, 10B, and 10C, the second lead 21, and the third leads 22 are not limited.

As shown in FIG. 2, the semiconductor element 30 is centrally located within the semiconductor device A10 as viewed in the z direction. As shown in FIGS. 10 to 15, the semiconductor element 30 is supported on the first leads 10A, 10B, and 10C, the second leads 21, and the third leads 22. The semiconductor element 30 is covered with the sealing resin 40. The semiconductor element 30 includes a semiconductor substrate 31, a semiconductor layer 32, a passivation film 33, an electrode 34, an insulating layer 35, and a plurality of electrode terminals 36. The semiconductor element 30 is a flip-chip LSI having a circuit inside.

The semiconductor element 30 is rectangular as viewed in the z direction as shown in FIG. 2, and has a plate-like shape as shown in FIGS. 10 to 13. The semiconductor element 30 has an element obverse surface 30a and an element reverse surface 30b. The element obverse surface 30a faces the first obverse surfaces 101 of the first leads 10A, 10B, and 10C, the second obverse surfaces 211 of the second leads 21, and the third obverse surfaces 221 of the third leads 22 in the z direction. The element reverse surface 30b faces away from the element obverse surface 30a in the z direction. As shown in FIG. 2 with broken lines, the element obverse surface 30a includes a first region 301 and a second region 302. The first region 301 includes the area where the element obverse surface 30a faces the first obverse surfaces 101 of the first leads 10A, 10B, and 10C and is located on the y2 side in the y direction. The second region 302 includes an area where the element obverse surface 30a faces the second obverse surfaces 211 of the second leads 21 and the third obverse surfaces 221 of the third leads 22 and is located on the y1 side in the y direction.

As shown in FIGS. 14 and 15, the semiconductor substrate 31 is provided with the semiconductor layer 32, the passivation film 33, the electrodes 34, the insulating layer 35, and the electrode terminals 36 on the z1 side in the z direction. The semiconductor substrate 31 is made of silicon (Si) or silicon carbide (SiC), for example. In the present embodiment, the surface of the semiconductor substrate 31 on the z2 side in the z direction forms the element reverse surface 30b.

As shown in FIGS. 10 to 13, the semiconductor layer 32 is disposed on the z1 side of the semiconductor substrate 31 in the z direction. The semiconductor layer 32 includes a plurality of p-type and n-type semiconductors resulting from doping with different amount of elements. The semiconductor layer 32 is formed with the switching circuit 321 and a control circuit 322 electrically connected to the switching circuit 321. The switching circuit 321 may be a metal-oxide-semiconductor field-effect transistor (MOSFET) or an insulated gate bipolar transistor (IGBT), for example. In this example of the semiconductor device A10, the switching circuit 321 is divided into two regions: a high-voltage region (upper arm circuit) and a low-voltage region (lower arm circuit). Each region is composed of one n-channel MOSFET. The control circuit 322 includes a gate driver for driving the switching circuit 321 and a bootstrap circuit for driving the high-voltage region of the switching circuit 321. The control circuit 322 performs necessary controls for the normal operation of the switching circuit 321. The semiconductor layer 32 further includes a wiring layer (not shown). The wiring layer interconnects the switching circuit 321 and the control circuit 322.

As shown in FIGS. 14 and 15, the passivation film 33 covers the surface of the semiconductor layer 32 that is located on the z1 side in the z direction. The passivation film 33 is electrically insulating. The passivation film 33 is composed of a silicon oxide film (SiO₂) in contact with the semiconductor layer 32, and a silicon nitride film (Si₃N₄) in contact with the silicon oxide film. In the present embodiment, the surface of the passivation film 33 that is located on the z1 side in the z direction forms the element obverse surface 30a.

As shown in FIG. 5, a plurality of electrodes 34 are formed on the element obverse surface 30a. The first region 301 includes a plurality of electrodes 34 having a shape elongated in the y direction, such as a triangular or rhombus shape as viewed in the z direction. In the present embodiment, the first region 301 includes a plurality of electrodes 34 having an isosceles triangular shape oriented with their vertices pointing toward the y1 side in the y direction. These electrodes 34 are aligned along the edge of the first region 301 on the y2 side in the y direction at equal intervals in the x direction. The first region 301 also includes a plurality of electrodes 34 having an isosceles triangular shape oriented with their vertices pointing toward the y2 side in the y direction. These electrodes 34 are aligned along the edge of the first region 301 on the y1 side in the y direction at equal intervals in the x direction. The vertices of the electrodes 34 on the y2 side in the y direction and the vertices of the electrodes 34 on the y1 side in the y direction point toward each other. The first region 301 also includes a plurality of electrodes 34 having a rhombus shape arranged in the spaces between the plurality of electrodes 34 arranged on the y2 in the y direction and those on the y1 side in the y direction. The electrodes 34 arranged on the y2 in the y direction are electrically connected to the first lead 10B each via an electrode terminal 36B. The electrodes 34 arranged on the y1 in the y direction are electrically connected to the first lead 10A each via an electrode terminal 36B. The electrodes 34 arranged in the spaces are electrically connected to the first lead 10C each via an electrode terminal 36B. The second region 302 includes a plurality of electrodes 34 having, for example, a rectangular shape as viewed in the z direction. The electrodes 34 in the second region 302 are isolated in position from each other. The electrodes 34 in the second region 302 includes those electrically connected to the second lead 21 and those electrically connected to the third lead 22, each via an electrode terminal 36A. Note that the shapes and arrangements of the electrodes 34 as viewed in the z direction are not limited. The electrodes 34 are arranged with a slit (gap) between each adjacent pair. In FIG. 5, the slits appear as line segments in plan view. The plan-view shape of the slits, however, is not limited to this. The slit may have a plan-view shape that appears a wavy or zig-zag line.

Each electrode 34 is in contact with the wiring layer formed in the semiconductor layer 32 through an opening (not shown) in the passivation film 33. This electrically connects each electrode 34 to the switching circuit 321 or the control circuit 322 in the semiconductor layer 32. In the present embodiment, the electrodes 34 are composed of a plurality of metal layers stacked on the passivation film 33 toward the z1 side in the z direction, including a first layer 34a, a second layer 34b, and a third layer 34c. The first layer 34a is in contact with the passivation film 33 and is made of Cu. The second layer 34b is in contact with the first layer 34a and is made of Ni. The third layer 34c is in contact with the second layer 34b and is made of Pd. The configuration of the electrodes 34 is not limited to such.

As shown in FIGS. 14 and 15, the insulating layer 35 is formed on the element obverse surface 30a and covers portions of the passivation film 33 and the electrodes 34. The insulating layer 35 is electrically insulating. In the present embodiment, the material of the insulating layer 35 is a phenolic resin. The material of the insulating layer 35 is not limited, and other insulating materials, such as a polyimide resin, may be used. The insulating layer 35 has a plurality of openings 35a. Each opening 35a exposes one of the electrodes 34. The insulating layer 35 can be formed by applying a photosensitive resin material using a spin coater, followed by photolithography, for example.

As shown in FIGS. 10 to 13, each electrode terminal 36 is disposed on the element obverse surface 30a and protrudes toward a corresponding one of the first obverse surfaces 101, the second obverse surfaces 211 and the third obverse surfaces 221. Also as shown in FIGS. 14 and 15, each electrode terminal 36 is in contact with an electrode 34 through an opening 35a of the insulating layer 35. Each electrode terminal 36 makes contact with the corresponding electrode 34 at its central portion as viewed in the z direction and overlaps with the insulating layer 35 at its peripheral portion. The electrode terminals 36 are electrically conductive.

As shown in FIGS. 14 and 15, each electrode terminal 36 includes a seed layer 361, a first plating layer 362, and a second plating layer 363. Each seed layer 361 is in contact with the corresponding electrode 34 and the insulating layer 35 and contains Cu. The seed layers 361 are formed by electroless plating, for example. The material and the method for forming the seed layers 361 are not particularly limited. For example, the seed layers 361 may be formed by sputtering. Each first plating layer 362 is sacked on the corresponding seed layer 361 and may be made of Cu or a Cu alloy. The first plating layers 362 may be formed by electroplating. The material of the first plating layers 362 is not particularly limited. Each second plating layer 363 is stacked on the corresponding first plating layer 362. Each second plating layer 363 is disposed between the corresponding first plating layer 362 and a bonding portion 5 and prevents the first plating layer 362 and the bonding portion 5 from compounding with each other. The material of the second plating layers 363 is not particularly limited, and metals capable of preventing the reaction, such as Ni and Fe, may be selected. In the present embodiment, since the first plating layers 362 contain Cu and the bonding portions 5 contain Sn, the second plating layers 363 may be made of Ni, for example. In the present embodiment, the second plating layers 363 are formed by electroplating. The material and the method for forming the second plating layers 363 are not particularly limited. In addition, the second plating layers 363 may not be essential. Each electrode terminal 36 has a bonding surface 365. Each bonding surface 365 faces away from the corresponding electrode 34 (and located to face the corresponding one of the first obverse surfaces 101, the second obverse surfaces 211, and the third obverse surfaces 221). Each bonding surface 365 is bonded to the metal layer 6 formed on the corresponding one of the first obverse surfaces 101, the second obverse surfaces 211, and the third obverse surfaces 221, via a bonding portion 5.

The plurality of electrode terminals 36 include a plurality of electrode terminals 36A and a plurality of electrode terminals 36B. As shown in FIGS. 2 and 5 the electrode terminals 36A are located in the second region 302 of the element obverse surface 30a. The electrode terminals 36B are located in the first region 301 of the element obverse surface 30a.

The electrode terminals 36A are electrically connected to the control circuit 322 of the semiconductor layer 32. As shown in FIG. 3, one of the electrode terminals 36A is electrically connected to the first obverse surface 101 of the first lead 10A. Two of the electrode terminals 36A are electrically connected to the third obverse surfaces 221 of the pair of third leads 22. The rest of the electrode terminals 36A are electrically connected to the second obverse surfaces 211 of the second leads 21. Hence, the first lead 10A, the third leads 22, and the second leads 21 are electrically connected to the control circuit 322. Each electrode terminal 36A is circular as viewed in the z direction (in plan view), and the bonding surface 365 (365A) of each electrode terminal 36A is also circular. Each bonding surface 365A has a diameter D1 (see FIG. 14), which may be, but not limited to, 100 μm, for example.

The electrode terminals 36B are electrically connected to the switching circuit 321 of the semiconductor layer 32. The electrode terminals 36B are electrically connected to the first obverse surfaces 101 of the first leads 10A, 10B, and 10C. Hence, the first leads 10A, 10B, and 10C are electrically connected to the switching circuit 321. Each electrode terminal 36B is circular as viewed in the z direction (in plan view), and the bonding surface 365 (365B) of each electrode terminal 36B is also circular. Each bonding surface 365B has a diameter D2 (see FIG. 15) that is greater than the diameter D1, and may be, but not limited to, 150 μm, for example. The area S2 of each bonding surface 365B is greater than the area S1 of each bonding surface 365A. Preferably, the area S2 is at least two times and at most four times greater than the area S1. The area S2 is greater than the area S1 because the electrode terminals 36B carry higher electric current than the electrode terminals 36A.

As shown in FIG. 3, the first obverse surfaces 101 of the first leads 10A, 10B, and 10C, the second obverse surfaces 211 of the second leads 21, and the third obverse surfaces 221 of the third leads 22 each have one or more metal layers 6 formed thereon. The metal layers 6 are located at the positions of the electrode terminals 36 of the semiconductor element 30. As shown in FIGS. 14 and 15, each metal layer 6 is disposed between an electrode terminal 36 and the first obverse surface 101 of a relevant first leas 10A, 10B, and 10C, or the second obverse surface 211 of a relevant second lead 21, or the third obverse surface 221 of a relevant third lead 22. The metal layer 6 is bonded to the electrode terminal 36 through a bonding portion 5. The metal layers 6 prevent the first leads 10A, 10B, 10C, and the second leads 21, and the third leads 22 from compounding with the bonding portions 5. Additionally, each metal layer 6 limits the extent to which the corresponding bonding portion 5 spreads in the process of bonding the semiconductor element 30.

In the present embodiment, each metal layer 6 includes a first layer 61, a second layer 62, and a third layer 63 as shown in FIGS. 14 and 15. Each first layer 61 is in contact with the first obverse surface 101 of a relevant first leas 10A, 10B, and 10C, or the second obverse surface 211 of a relevant second lead 21, or the third obverse surface 221 of a relevant third lead 22. In the present embodiment, since the first leads 10A, 10B, and 10C, the second leads 21, and the third leads 22 contain Cu, and the bonding portions 5 contain Sn, the first layers 61 are made of Ni, for example. Each second layer 62 is stacked in contact with the corresponding first layer 61. The material of the second layers 62 is not limited, and Pd may be one example. Each third layer 63 is stacked in contact with the corresponding second layer 62. The third layers 63 are made of a material that is relatively highly wettable by the bonding portions 5 (solder). The material of the third layers 63 is not limited, and Au may be one example. The method for forming the metal layers 6 is not particularly limited.

The plurality of metal layers 6 include a plurality of metal layers 6A and a plurality of metal layers 6B.

As shown in FIG. 3, each metal layer 6A is disposed on one of the second obverse surfaces 211, the third obverse surfaces 221, and the first obverse surface 101 of the first lead 10A. Each metal layer 6A is bonded to an electrode terminal 36A of the semiconductor element 30. Each metal layer 6A is circular as viewed in the z direction, which matches the shape of the bonding surface 365A of each electrode terminal 36A. As shown in FIG. 14, each metal layer 6A has a diameter D3 that is greater than the diameter D1 of each bonding surface 365A. As viewed in the z direction as shown in FIG. 3, each electrode terminal 36A (each bonding surface 365A) is encompassed within the corresponding metal layer 6A.

As shown in FIG. 3, each metal layer 6B is disposed on the first obverse surface 101 of the first lead 10A, 10B, or 10C. Each metal layer 6B is bonded to an electrode terminal 36B of the semiconductor element 30. Each metal layer 6B is circular as viewed in the z direction, which matches the shape of the bonding surface 365B of each electrode terminal 36B. As shown in FIG. 15, each metal layer 6B has a diameter D4 that is greater than the diameter D2 of each bonding surface 365B. As viewed in the z direction as shown in FIG. 3, each electrode terminal 36B (each bonding surface 365B) is encompassed within the corresponding metal layer 6B.

In the present embodiment, when the diameter D2 of the bonding surfaces 365B is n times greater than the diameter D1 of the bonding surfaces 365A (where n>1), the diameter D4 of the metal layers 6B is also n times greater the diameter D3 of the metal layers 6A. That is, the ratio between the diameter D1 of the bonding surfaces 365A and the diameter D2 of the bonding surfaces 365B is the same as the ratio between the diameter D3 of the metal layers 6A and the diameter D4 of the metal layers 6B. Additionally, the area S2 of each bonding surface 365B is n² times greater than the area S1 of each bonding surface 365A, and the area S4 of each metal layer 6B is n² times greater than the area S2 of each metal layer 6A. Hence, the ratio between the area S1 of each bonding surface 365A and the area S2 of each bonding surface 365B is the same as the ratio between the area S3 of each metal layer 6A and the area S4 of each metal layer 6B. However, the electrode terminals 36 and the metal layers 6 may involve deviations due to manufacturing errors. The ratio between the areas S3 and S4 is ideally equal to the ratio between the areas S1 and S2. Considering the potential dimensional deviations, however, the ratio between the areas S3 and S4 may be within ±10% of the ratio between the areas S1 and S2.

Additionally, the difference between the diameter D4 of the metal layers 6B and the diameter D2 of the bonding surfaces 365B is n times greater than the difference between the diameter D3 of the metal layers 6A and the diameter D1 of the bonding surfaces 365A. That is, the difference between the diameter D3 of the metal layers 6B and the diameter D1 of the bonding surfaces 365B is smaller than the difference between the diameter D4 of the metal layers 6A and the diameter D2 of the bonding surfaces 365A. In the present embodiment, with the metal layers 6A and 6B and the bonding surfaces 365A and 365B being circular, the respective diameters are examples of their “representative lengths”.

Each bonding portion 5 is electrically conductive and positioned between an electrode terminal 36 and a metal layer 6, electrically connecting the electrode terminal 36 and the metal layer 6. In the present embodiment, the bonding portions 5 are made of solder containing Sn (such as SnAg), for example. The material of the bonding portions 5 is not specifically limited.

The plurality of bonding portions 5 include a plurality of bonding portions 5A and a plurality of bonding portions 5B. Each bonding portion 5A is positioned between the bonding surface 365A of an electrode terminal 36A and a metal layer 6A, bonding the electrode terminal 36A and the metal layer 6A. Each bonding portion 5A is shaped like a frustoconical cone, with its upper surface in contact with the bonding surface 365A and its lower surface in contact with the metal layer 6A. Each bonding portion 5B is positioned between the bonding surface 365B of an electrode terminal 36B and a metal layer 6B, bonding the electrode terminal 36B and the metal layer 6. Each bonding portion 5b is shaped like a frustoconical cone, with its upper surface in contact with the bonding surface 365B and its lower surface in contact with the metal layer 6B.

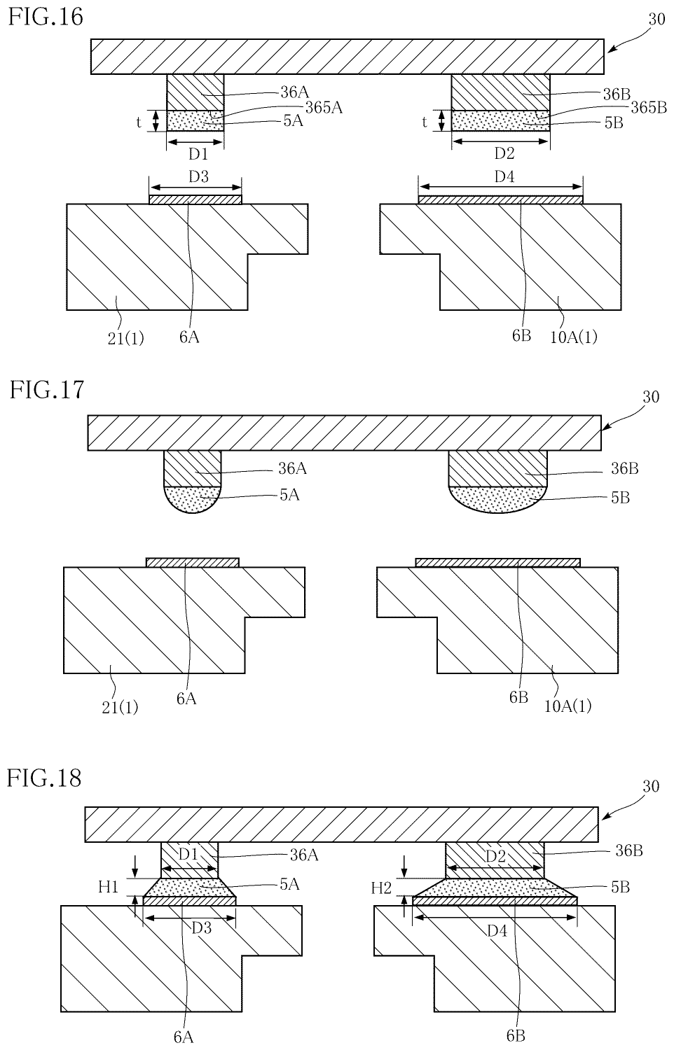

FIGS. 16 to 18 are schematic illustrations of a method of flip-chip bonding the semiconductor element 30 onto the conductive member 1.

As shown in FIG. 16, the semiconductor element 30 includes an electrode terminal 36A having a bonding surface 365A on which a bonding portion 5A is already deposited through electroplating. The semiconductor element 30 also includes an electrode terminal 36B having bonding surface 365B on which a bonding portion 5B is already deposited through electroplating. As the bonding surfaces 365A and 365B are circular, the bonding portions 5A and 5B take on a cylindrical shape with a thickness t.

FIG. 17 illustrates the bonding portions 5A and 5B in a molten state due to reflow. The bonding portions 5A and 5B in the molten state take a hemispherical shape due to surface tension. In this state, the semiconductor element 30 is moved toward the conductive member 1 to bring the bonding portions 5A and 5B into contact with the metal layers 6A and 6B, respectively.

The third layer 63 of each of the metal layers 6A and 6B has relatively good solder wettability. This ensures, as shown in FIG. 18, that the bonding portion 5A spreads across the entire surface of the metal layer 6A without overflowing from the metal layer 6A as viewed in the z direction, and that the bonding portion 5B spreads across the entire surface of the metal layer 6B without overflowing from the metal layer 6B as viewed in the z direction. The bonding portion 5A forms a frustoconical shape whose cross-sectional area orthogonal to the z direction gradually increases from the electrode terminal 36A to the metal layer 6A in the z direction. Similarly, the bonding portion 5B forms a frustoconical shape whose cross-sectional area orthogonal to the z direction gradually increases from the electrode terminal 36B to the metal layer 6B in the z direction. When cooled, the bonding portion 5A solidifies to bond the electrode terminal 36A and the metal layer 6A, and the bonding portion 5B solidifies to bond the electrode terminal 36B and the metal layer 6B.

The volume of the bonding portion 5A in the state shown in FIG. 16 is given by π·(D1/2)²·t. The volume of the bonding portion 5A in the state shown in FIG. 18 is given by (1/3)·π·{(D1/2)²+(D1/2)·(D3/2)+(D3/2)²}·H1, where H1 represents the height of the bonding portion 5A. Since the volume of the bonding portion 5A remains unchanged, the height H1 is given as follows:

$$H 1 = 3 \cdot D {1}^{2} \cdot t / ( D {1}^{2} + D 1 \cdot D 3 + D {3}^{2} ) .$$

Similarly, the height H2 of the bonding portion 5B in the state shown in FIG. 18 is given as follows:

H2=3·D2²·t/(D2²+D2·D4+D4²).

In the present embodiment, since D2=n·D1 and D4=n·D3, the following is given:

$$\begin{matrix}H 2 = 3 \cdot {( n \cdot D 1 )}^{2} \cdot t / \{ {( n \cdot D 1 )}^{2} + ( n \cdot D 1 ) \cdot ( n \cdot D 3 ) + {( n \cdot D 3 )}^{2} \} \\ = 3 \cdot D {1}^{2} \cdot t / ( D {1}^{2} + D 1 \cdot D 3 + D {3}^{2} ) \\ = H 1\end{matrix}$$

As shown above, the height H1 of the bonding portion 5A and the height H2 of the bonding portion 5B are equal.

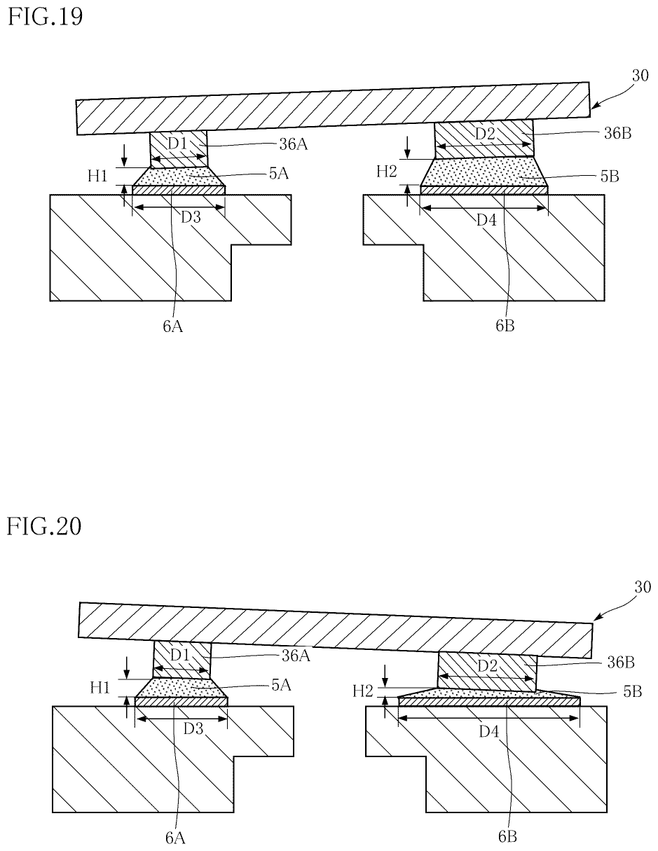

FIGS. 19 and 20 are views for comparison with FIG. 18, showing examples in which the diameter D4 of the metal layer 6B differs from that of the semiconductor device A10.

In the example shown in FIG. 19, the diameter D4 of the metal layer 6B is smaller than n·D3, and the difference between the diameter D4 and the diameter D2 is equal to the difference between the diameter D3 and the diameter D1. In this case, the spreading of the bonding portion 5B is limited by the metal layer 6B, so that the resulting bonding portion 5B has the height H2 that is greater than that in the semiconductor device A10. This means that the height H2 of the bonding portion 5B is greater than the height H1 of the bonding portion 5A, resulting in the semiconductor element 30 being tilted. That is, tilting of the semiconductor element 30 cannot be prevented by simply increasing the diameter of the metal layer 6 by a fixed amount from the diameter of the corresponding bonding surface 365.

FIG. 20 shows an example in which the diameter D4 of the metal layer 6B is greater than n·D3. In this case, the metal layer 6B spreads across the entire surface of the bonding portion 5B, resulting in the height H2 of the bonding portion 5B smaller than that of the semiconductor device A10. This means that the height H2 of the bonding portion 5B is smaller than the height H1 of the bonding portion 5A, resulting in the semiconductor element 30 being tilted.

As illustrated in FIGS. 18 to 20, the diameters of the metal layers 6 need to be appropriately designed to prevent tilting of the semiconductor element 30. Specifically, when the diameter D2 of the bonding surface 365B is n times greater than the diameter D1 of the bonding surface 365A, the diameter D4 of the metal layer 6B needs to be n times greater than the diameter D3 of the metal layer 6A. In other words, the ratio between the diameters D3 and D4 needs to be matched to the ratio between the diameters D1 and D2. Since the bonding surfaces 365A and 365B and the metal layers 6A and 6B are all circular, matching the diameter ratios is equivalent to matching the ratio between the area S3 of the metal layer 6A and the area S4 of the metal layer 6B to the ratio between the area S1 of the bonding surface 365A and the area S2 of the bonding surface 365B.

The sealing resin 40 entirely covers the semiconductor element 30 and partly covers the first leads 10A, 10B, and 10C, the second leads 21, and the third leads 22. The sealing resin 40 is made of a material containing a black epoxy resin, for example, but the material of the sealing resin 40 is not limited. The sealing resin 40 is rectangular as viewed in the z direction, and has a top surface 41, a bottom surface 42, a pair of first side surfaces 431, and a pair of second side surfaces 432 as shown in FIGS. 6 to 9.

As shown in FIGS. 10 to 13, the top surface 41 faces the same side as the first obverse surfaces 101 of the first leads 10A, 10B, and 10C in the z direction. As shown in FIGS. 6 to 9, the bottom surface 42 faces away from the top surface 41. As shown in FIG. 4, the first reverse surfaces 102 of the first leads 10A, 10B, and 10C, the second reverse surfaces 212 of the second leads 21, and the third reverse surfaces 222 of the third leads 22 are exposed from the bottom surface 42.

As shown in FIGS. 8 and 9, the pair of first side surfaces 431 are connected to the top surface 41 and the bottom surface 42 and face in the x direction. The pair of first side surfaces 431 are spaced apart from each other in the x direction. As shown in FIGS. 6, 7, and 11 to 13, the first end surfaces 121 of the first leads 10A, 10B, and 10C, the fourth end surfaces 214 of the second leads 21, and the third end surfaces 223 of the third leads 22 are exposed from, and flush with the first side surfaces 431.

As shown in FIGS. 6 and 7, the pair of second side surfaces 432 are connected to the top surface 41, the bottom surface 42, and the pair of first side surfaces 431 and face in the y direction. The pair of second side surfaces 432 are spaced apart from each other in the y direction. As shown in FIG. 10, the second end surfaces 213 of the second leads 21 are exposed from, and flush with the second side surface 432 that is located on the y1 side in the y direction. The sub-end surfaces 131 of the first lead 10B are exposed from, and flush with the second side surface 432 that is located on the y2 side in the y direction.

The following describes advantages of the semiconductor device A10.

According to the present embodiment, the conductive member 1 includes the metal layers 6 located at the positions of the electrode terminals 36 of the semiconductor element 30. Each electrode terminal 36 is bonded to the conductive member 1 via a bonding portion 5 and a metal layer 6. In the process of bonding the semiconductor element 30, the bonding portion 5 on the bonding surface 365 of each electrode terminal 36 melts and spreads across the entire surface of the metal layer 6, without overflowing from the metal layer 6 as viewed in the z direction. That is, each metal layer 6 serves to limit the extent to which the corresponding bonding portion 5 spreads in a molten state, thereby controlling the thickness of the bonding portion 5. The semiconductor device A10 can therefore prevent tilting of the semiconductor element 30 relative to the conductive member 1. As in the example shown in FIG. 19, when the difference between the diameter D3 of each metal layer 6A and the diameter D1 of each bonding surface 365A is equal to the difference between the diameter D4 of each metal layer 6B and the diameter D2 of each bonding surface 365B, the height H2 of each bonding portion 5B becomes greater than the height H1 of each bonding portion 5A. In the present embodiment, the difference between the diameters D3 and D1 is smaller than the difference between the diameters D4 and D2. Hence, the semiconductor device A10 is configured to prevent that the height H2 is greater than the height H1.

According to the present embodiment, in addition, the ratio between the area S1 of each bonding surface 365A and the area S2 of each bonding surface 365B is the same as the ratio between the area S3 of each metal layer 6A and the area S4 of each metal layer 6B. This results in the height H1 of each bonding portion 5A and the height H2 of each bonding portion 5B being equal to each other as shown in FIGS. 16 to 18. Consequently, the semiconductor device A10 prevents tilting of the semiconductor element 30 relative to the conductive member 1. Due to manufacturing errors, the ratio between the areas S1 and S2 may not be exactly equal to the ratio between the areas S3 and S4. However, as long as the difference between the ratios is within ±10%, the semiconductor device A10 effectively prevents tilting of the semiconductor element 30 relative to the conductive member 1.

According to the present embodiment, in addition, the electrode terminals 36A are in the second region 302 located on the y1 side in the y direction of the element obverse surface 30a, and the electrode terminals 36B are in the first region 301 located on the y2 side in the y direction of the element obverse surface 30a. Hence, when there is a difference between the height H1 of the bonding portions 5A, which bond the electrode terminals 36A, and the height H2 of the bonding portions 5B, which bond the electrode terminals 36B, it often results in tilting of the semiconductor element 30. In the semiconductor device A10 of the present embodiment, however, the heights H1 and H2 are ensured to be equal by appropriately adjusting the areas of the metal layers 6A and 6B, so that tilting of the semiconductor element 30 is prevented.

According to the present embodiment, in addition, the semiconductor element 30 is mounted on the conductive member 1 using flip-chip bonding. Compared with a semiconductor device that connects the electrodes 34 and the leads with wires, the semiconductor device A10 ensures lower resistance in the electrical paths and a lower profile. As compared with a semiconductor device having a semiconductor element electrically connected with wires, the semiconductor device A10 can accommodate a larger semiconductor element 30 provided that the outer size of the sealing resin 40 is the same. As compared with a semiconductor device having a semiconductor element electrically connected with wires, the semiconductor device A10 can use a smaller sealing resin 40 to accommodate the semiconductor element 30 of the same size.

In the present embodiment, each metal layer 6 includes the first layer 61, the second layer 62, and the third layer 63, but this is a non-limiting example. The number of layers forming each metal layer 6, as well as the materials of the respective layers, is not limited. In the present embodiment, in addition, the semiconductor element 30 is an LSI, but this is a non-limiting example. The type of the semiconductor element 30 is not limited.

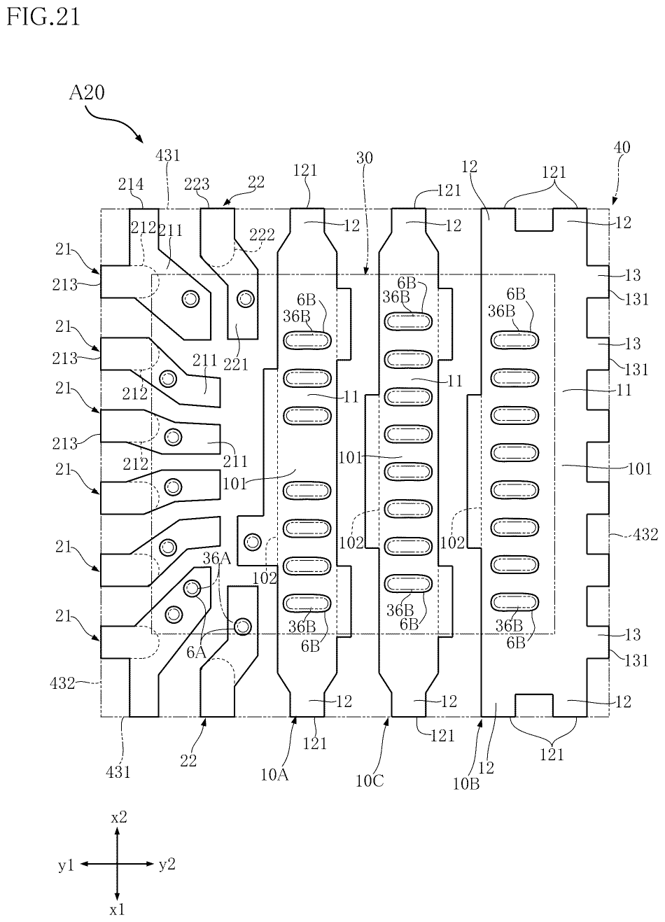

FIGS. 21 to 24 show other embodiments of the present disclosure. In these figures, components similar or identical to those of the embodiment described above are indicated by the same reference numerals.

### Second Embodiment

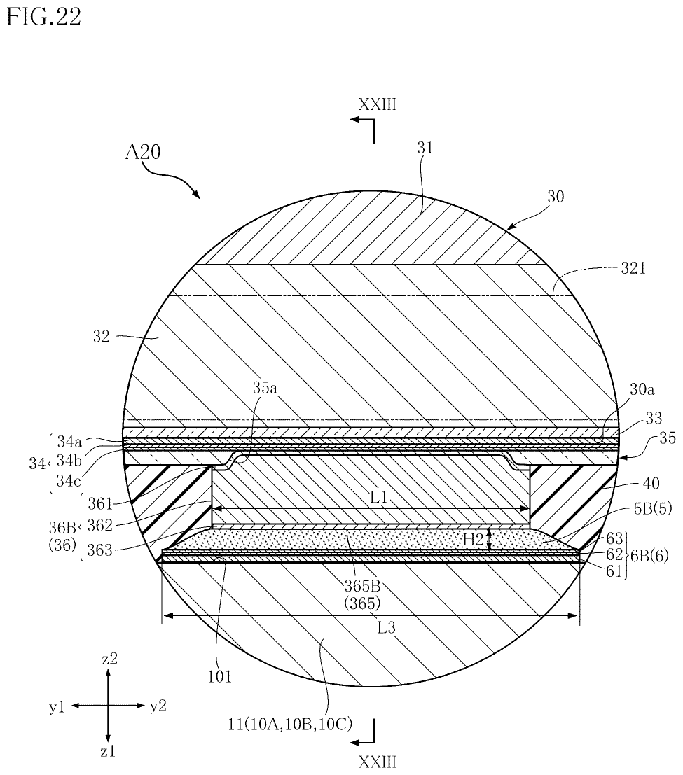

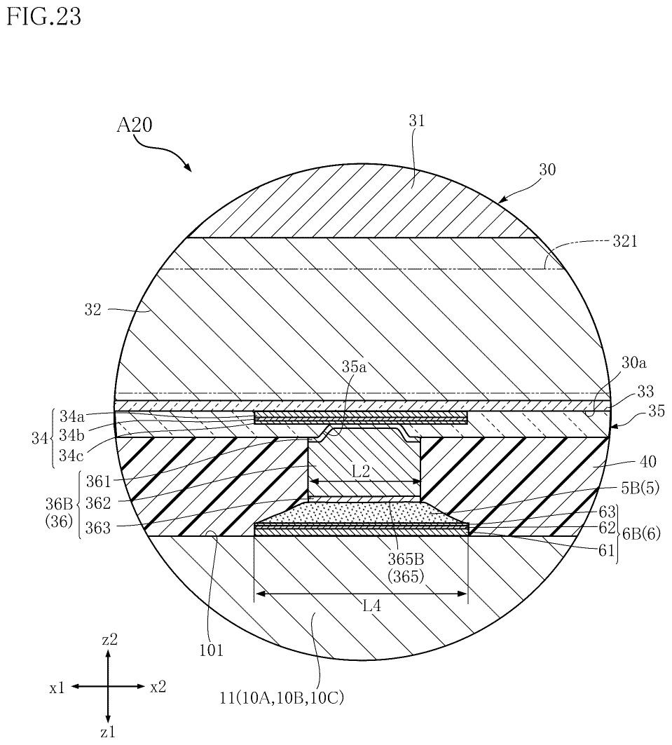

FIG. 21 is a view for illustrating a semiconductor device A20 according to a second embodiment of the present disclosure. FIG. 21 is a plan view of the semiconductor device A20, corresponding to FIG. 3. For the convenience of description, FIG. 21 shows the sealing resin 40 and the semiconductor element 30 as transparent, with their outlines indicated by imaginary line (two-dot-dash lines). FIG. 22 is an enlarged sectional view of the semiconductor device A20, showing a portion corresponds to FIG. 15. FIG. 23 is a sectional view taken along line XXIII-XXIII in FIG. 22. The semiconductor device A20 of the present embodiment differs from the first embodiment in the shapes of the electrode terminals 36B and the metal layers 6B. Other configurations and operations are similar to those of the first embodiment.

In the present embodiment, the electrode terminals 36B have an identical elliptical shape as viewed in the z direction (in plan view). Consequently, the bonding surfaces 365B of the respective electrode terminal 36B have an identical shape of an ellipse. As shown in FIG. 21, the bonding surface 365B of each electrode terminal 36B has the longitudinal direction (the direction of the major diameter) orthogonal to the direction in which the first leads 10A, 10C, and 10B extend. The relation between the longitudinal direction of the bonding surfaces 365B and the extending directions of the first leads 10A, 10C, 10B is not limited to such. While the dimensions of the bonding surfaces 365B are not limited, each bonding surface 365B may have the major diameter (the dimension in the y direction) L1 (see FIG. 22) of 300 μm for example, and the minor diameter (the dimension in the x direction) L2 (see FIG. 23) of 100 μm, for example. The area S2 of each bonding surface 365B is greater than the area S1 of each bonding surface 365A. Preferably, the area S2 is at least two times and at most four times greater than the area S1.

In the present embodiment, in addition, the metal layers 6B are also elliptical as viewed in the z direction, matching the shape of the bonding surfaces 365B. The metal layers 6B have the major diameter L3 (the dimension in the y direction) greater than the major diameter L1 of the bonding surfaces 365B as shown in FIG. 22, and have the minor diameter L4 (the dimension in the x direction) greater than the minor diameter L2 of the bonding surfaces 365 as shown in FIG. 23. As shown in FIG. 21, in addition, each electrode terminal 36B (each bonding surface 365B) is encompassed within the corresponding metal layer 6B.

In the present embodiment, the ratio between the area S1 of each bonding surface 365A and the area S2 of each bonding surface 365B is the same as the ratio between the area S3 of each metal layer 6A and the area S4 of each metal layer 6B. Note, however, that the electrode terminals 36 and the metal layers 6 may involve deviations due to manufacturing errors. The ratio between the areas S3 and S4 is ideally equal to the ratio between the areas S1 and S2. Considering the potential dimensional deviations, however, the ratio between the areas S3 and S4 may be within ±10% of the ratio between the areas S1 and S2.

Each bonding portion 5A has the shape of a frustum (including a frustum of circular cone, a frustum of elliptical cone, and a frustum of pyramid) with the upper surface area S1, the lower surface area S3, and the height H1. The volume each bonding portion 5A is thus given by: (1/3)·{S1+√(S1+S3)+S3}·*H1. The volume of each bonding portion 5A before bonding is given by S1·t, the following is established.

H1=3·S1·t/{S1+√(S1+S3)+S3}

Similarly, the height H2 of each bonding portion 5B is given by:

H2=3·S2·t/{S2+√(S2+S4)+S4}.

In the present embodiment, the ratio between the areas S1 and S2 is equal to the ratio between the areas S3 and S4. Then, with S2=n′·S1 and S4=n′·S3, the following is established.

$$\begin{matrix}H 2 = 3 \cdot {n}^{′} \cdot S 1 \cdot t / \{ {n}^{′} \cdot S 1 + √ ( {n}^{′} \cdot S 1 + {n}^{′} \cdot S 3 ) + {n}^{′} \cdot S 3 \} \\ = 3 \cdot S 1 \cdot t / \{ S 1 + √ ( S 1 + S 3 ) + S 3 \} \\ = H 1\end{matrix}$$

That is, the height H1 of the bonding portions 5A is equal to the height H2 of the bonding portions 5B. As clarified above, regardless of the shapes of the bonding surfaces 365 and the metal layers 6, the height H1 and the height H2 of the bonding portions 5A and 5B, respectively, are ensured to be equal, on condition that the ratio between the area S1 of each bonding surface 365A and the area S2 of each bonding surface 365B is equal to the ratio between the area S3 of each metal layer 6A and the area S4 of each metal layer 6B.

The difference between the diameter D3 of the metal layers 6A and the diameter D1 of the bonding surfaces 365A is smaller than the difference between the major diameter L3 of the metal layers 6B and the major diameter L1 of the bonding surfaces 365B. Additionally, the difference between the diameter D3 of the metal layers 6A and the diameter D1 of the bonding surfaces 365A is smaller than the difference between the minor diameter L4 of the metal layers 6B and the minor diameter L2 of the bonding surfaces 365B. In the present embodiment, the metal layers 6A and the bonding surfaces 365A are circular, so that their diameters are examples of the “representative lengths”. The metal layers 6B and the bonding surfaces 365B are elliptical, so that their major or minor diameters are examples of the “representative lengths”.

In the present embodiment, the conductive member 1 is formed with the metal layers 6 at the positions of the electrode terminals 36 of the semiconductor element 30. Each metal layer 6 serves to limit the extent to which the corresponding bonding portion 5 spreads in a molten state, thereby controlling the thickness of the bonding portion 5. The semiconductor device A20 can therefore prevent tilting of the semiconductor element 30 relative to the conductive member 1. In the present embodiment, in addition, the difference between the diameters D3 and D1 is smaller than the difference between the major diameters L3 and L1 and is also smaller than the difference between the minor diameters L4 and L2. The semiconductor device A20 is thus configured to prevent that the height H2 is greater than the height H1. In the present embodiment, the ratio between the areas S1 and S2 is equal to the ratio between the areas S3 and S4. This ensures that the heights H1 and H2 are equal. The semiconductor device A20 can therefore prevent tilting of the semiconductor element 30 relative to the conductive member 1. The semiconductor device A20 has a configuration in common with the semiconductor device A10, thereby achieving the same effect as the semiconductor device A10.

While the bonding surface 365 of each electrode terminal 36 is circular or elliptical in the first and second embodiments described above, these are non-limiting examples. The bonding surface 365 of each electrode terminal 36 may have either a rectangular or polygonal shape. Each metal layer 6 is formed to have a shape that matches the shape of the bonding surface 365 of an electrode terminal 36 to which the metal layer 6 is bonded. Also, the area of each metal layer 6 is determined by the area of the relevant bonding surface 365. As clarified above, regardless of the shapes of the bonding surfaces 365 and the metal layers 6, the height H1 and the height H2 of the bonding portions 5A and 5B, respectively, are ensured to be equal, on condition that the ratio between the area S1 of each bonding surface 365A and the area S2 of each bonding surface 365B is equal to the ratio between the area S3 of each metal layer 6A and the area S4 of each metal layer 6B. When a bonding surface 365 and a metal layer 6 have a rectangular or polygonal shape, the length of a side or diagonal line of the shape is an example of the representative length”. The difference between two representative lengths refers to the difference between the lengths of two similar shapes measured at corresponding portions, such as the lengths of a bonding surface 365 and a metal layer 6, which have similar shapes, measured along their diagonal lines or corresponding sides.

### Third Embodiment

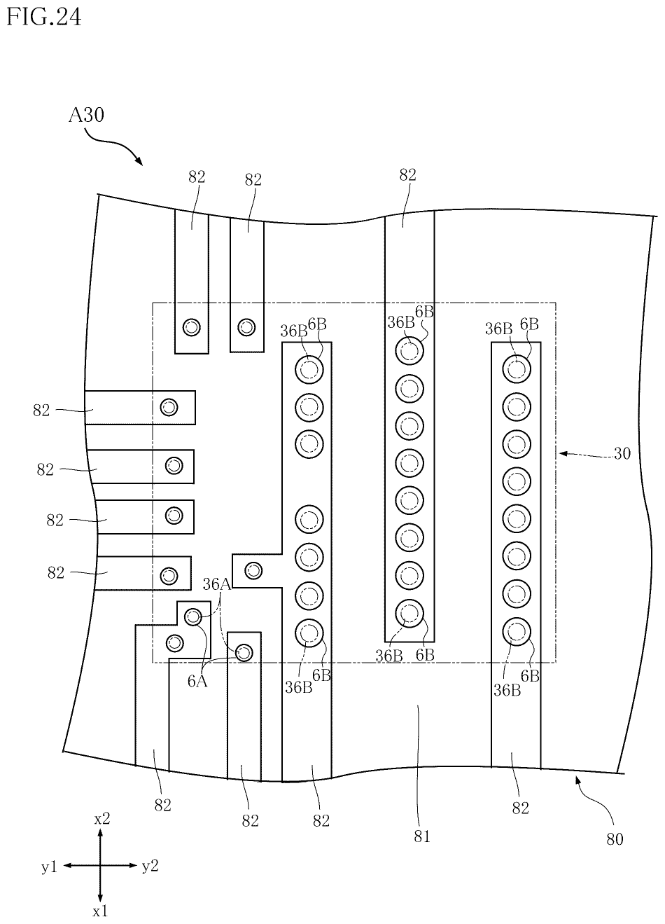

FIG. 24 is a view for illustrating a semiconductor device A30 according to a third embodiment of the present disclosure. FIG. 24 is a plan view of a portion of the semiconductor device A30 and corresponds to FIG. 3. For the convenience of description, FIG. 24 shows the sealing resin 40 and the semiconductor element 30 as transparent, with their outlines indicated by imaginary line (two-dot-dash lines). The semiconductor device A30 of the present embodiment differs from the first embodiment in that the semiconductor element 30 is mounted on a wiring substrate instead of the leads. Other configurations and operations are similar to those of the first embodiment. Note that features of the first and second embodiments may be combined in any way.

In the first and second embodiments, the semiconductor element 30 are mounted on the first leads 10A, 10B, and 10C, the second leads 21, and the third leads 22, and the electrode terminals 36 are bonded to these leads. The semiconductor element 30, however, may be bonded to a conductive member other than the leads. In the semiconductor device A30 of the third embodiment, the semiconductor element 30 is mounted on a wiring substrate, and the electrode terminals 36 are bonded to the wiring of the wiring substrate as described below.

The semiconductor device A30 includes a wiring substrate 80 instead of the first leads 10A, 10B, and 10C, the second leads 21, and the third leads 22. The wiring substrate 80 includes an insulating substrate 81 and a plurality of wirings 82. The insulating substrate 81 is a rectangular plate made of an electrically insulating material, such as a glass epoxy resin or a ceramic material. The material and the shape of the insulating substrate 81 are not limited. The wirings 82 are made of Cu, for example, and formed on the insulating substrate 81. The material and the shape of the wirings 82 are not limited.

The semiconductor element 30 is mounted using flip-chip bonding, with the element obverse surface 30a facing the wiring substrate 80. The electrode terminals 36A and 36B are each bonded to one of the wirings 82 of the wiring substrate 80. Each wiring 82 is formed with one or more metal layers 6. The metal layers 6 are located at the positions of the electrode terminals 36 of the semiconductor element 30. Each metal layer 6 is interposed between a wiring 82 and an electrode terminal 36, and an electrode terminal 36 is bonded to the metal layer 6 via a bonding portion 5. The metal layer 6 prevents the wiring 82 and the bonding portion 5 from compounding with each other and restricts the region to which the bonding portion 5 spreads in the process of bonding the semiconductor element 30. Similarly to the first embodiment, the metal layers 6 includes a plurality of metal layers 6A and a plurality of metal layers 6B. Each metal layer 6A is bonded to an electrode terminal 36A of the semiconductor element 30. Each metal layer 6B is bonded to an electrode terminal 36B of the semiconductor element 30. The entire semiconductor element 30 and at least a portion of the wiring substrate 80 are covered with the sealing resin 40 (not shown in FIG. 24). Note that additional components may be mounted on the wiring substrate 80 or that leads may be bonded to the wiring substrate for mounting the semiconductor device A30.

In the present embodiment, the wirings 82 are formed with the metal layers 6 at the positions of the electrode terminals 36 of the semiconductor element 30. Each metal layer 6 serves to limit the extent to which the corresponding bonding portion 5 spreads in a molten state, thereby controlling the thickness of the bonding portion 5. The semiconductor device A30 can therefore prevent tilting of the semiconductor element 30 relative to the wiring substrate 80. In the present embodiment, the difference between the diameters D3 and D1 is smaller than the difference between the diameters D4 and D2. Consequently, the semiconductor device A30 is configured to prevent that the height H2 is greater than the height H1. In the present embodiment, in addition, the ratio between the areas S1 and S2 is equal to the ratio between the areas S3 and S4. This ensures that the heights H1 and H2 are equal. The semiconductor device A30 can therefore prevent tilting of the semiconductor element 30 relative to the conductive member 1. The semiconductor device A30 has a configuration in common with the semiconductor device A10, thereby achieving the same effect as the semiconductor device A10.

The semiconductor device according to the present disclosure is not limited to the embodiments described above. Various modifications in design may be made freely in the specific structure of each part of the semiconductor device according to the present disclosure.

### Clause 1.

A semiconductor device comprising:
a semiconductor element (30) including an element obverse surface (30a) and an element reverse surface (30b) facing away from each other in a thickness direction, and a first electrode terminal (36A) and a second electrode terminal (36B) disposed on the element obverse surface;
a conductive member (1) electrically connected to the semiconductor element;
a first metal layer (6A) formed on the conductive member and bonded to the first electrode terminal; and
a second metal layer (6B) formed on the conductive member and bonded to the second electrode terminal,
wherein the first electrode terminal includes a first bonding surface (365A) facing the first metal layer,
the second electrode terminal includes a second bonding surface (365B) facing the second metal layer,
a first area (S1) of the first bonding surface is smaller than a second area (S2) of the second bonding surface, and
a difference between a representative length of the first metal layer and a corresponding representative length of the first bonding surface is smaller than a difference between a representative length of the second metal layer and a corresponding representative length of the second bonding surface.

### Clause 2.

The semiconductor device according to Clause 1, wherein a ratio between a third area (S3) of the first metal layer and a fourth area (S4) of the second metal layer is within ±10% of a ratio between the first area and the second area.

### Clause 3.

The semiconductor device according to Clause 2, wherein the ratio between the third area and the fourth area is equal to the ratio between the first area and the second area.

### Clause 4.

The semiconductor device according to Clause 2 or 3, wherein the second area is at least two times and at most four times greater than the first area.

### Clause 5. (Second Embodiment, FIGS. 21 to 23)

The semiconductor device according to any one of Clauses 1 to 4, wherein the first bonding surface and the first metal layer are circular, and the second bonding surface and the second metal layer are elliptical.

### Clause 6. (First Embodiment)

The semiconductor device according to any one of Clauses 1 to 4, wherein the first bonding surface and the first metal layer are circular, and the second bonding surface and the second metal layer are circular.

### Clause 7. (FIGS. 14 and 15)

The semiconductor device according to any one of Clauses 1 to 6, wherein the first metal layer and the second metal layer include:
a first layer (61) in contact with the conductive member and contains Ni;
a second layer (62) in contact with the first layer and contains Pd; and
a third layer (63) in contact with the second layer and contains Au.

### Clause 8.

The semiconductor device according to any one of Clauses 1 to 7, wherein the first electrode terminal and the second electrode terminal contain Cu.

### Clause 9.

The semiconductor device according to any one of Clauses 1 to 8, further comprising:
a first bonding portion (5A) interposed between the first bonding surface and the first metal layer; and
a second bonding portion (5B) interposed between the second bonding surface and the second metal layer.

### Clause 10.

The semiconductor device according to Clause 9, wherein the first bonding portion and the second bonding portion contain solder.

### Clause 11. (FIGS. 2, 3 and 5)

The semiconductor device according to any one of Clauses 1 to 10, wherein the semiconductor element includes a plurality of third electrode terminals that are identical in shape to the first electrode terminal, and a plurality of fourth electrode terminals that are identical in shape to the second electrode terminal, and
the first electrode terminal and the plurality of third electrode terminals are disposed on the element obverse surface at a location on a first side in a first direction orthogonal to the thickness direction, and the second electrode terminal and the plurality of fourth electrode terminals are disposed on the element obverse surface at a location on a second side in the first direction.

### Clause 12.

The semiconductor device according to any one of Clauses 1 to 11, wherein the conductive member includes a first lead (10A), and
the first metal layer and the second metal layer are formed on the first lead.

### Clause 13.

The semiconductor device according to any one of Clauses 1 to 11, wherein the conductive member includes a first lead (10A, 10B, and 10C) and a second lead (21),
the first metal layer is formed on the second lead, and
the second metal layer is formed on the first lead.

### Clause 14. (Third Embodiment, FIG. 24)

The semiconductor device according to any one of Clauses 1 to 11, further comprising an insulating substrate (81),
wherein the conductive member is a wiring (82) formed on the insulating substrate.

### REFERENCE NUMERALS

A10, A20, A30: semiconductor device
1: conductive member
10A, 10B, and 10C: first lead
11: main section
12: side section
13: projection
101: first obverse surface
102: first reverse surface
121: first end surface
131: sub-end surface
21: second lead
211: second obverse surface
212: second reverse surface
213: second end surface
214: fourth end surface
22: third lead
221: third obverse surface
222: third reverse surface
223: third end surface
30: semiconductor element
30a: element obverse surface
301: first region
302: second region
30b: element reverse surface
31: semiconductor substrate
32: semiconductor layer
321: switching circuit
322: control circuit
33: passivation film
34: electrode
34a: first layer 34b: second layer
34c: third layer
35: insulating layer
35a: opening
36, 36A, 36B: electrode terminal
361: seed layer
362: first plating layer
363: second plating layer
365, 365A, 365B: bonding surface
5, 5A, 5B: bonding portion
40: sealing resin
41: top surface
42: bottom surface
431: first side surface
432: second side surface
6, 6A, 6B: metal layer
61: first layer
62: second layer
63: third layer
80: wiring substrate
81: insulating substrate
82: wiring

1. A semiconductor device comprising:
a semiconductor element including an element obverse surface and an element reverse surface facing away from each other in a thickness direction, and a first electrode terminal and a second electrode terminal disposed on the element obverse surface;
a conductive member electrically connected to the semiconductor element;
a first metal layer formed on the conductive member and bonded to the first electrode terminal; and
a second metal layer formed on the conductive member and bonded to the second electrode terminal,
wherein the first electrode terminal includes a first bonding surface facing the first metal layer,
the second electrode terminal includes a second bonding surface facing the second metal layer,
a first area of the first bonding surface is smaller than a second area of the second bonding surface, and
a difference between a representative length of the first metal layer and a corresponding representative length of the first bonding surface is smaller than a difference between a representative length of the second metal layer and a corresponding representative length of the second bonding surface.

2. The semiconductor device according to claim 1, wherein a ratio between a third area of the first metal layer and a fourth area of the second metal layer is within ±10% of a ratio between the first area and the second area.

3. The semiconductor device according to claim 2, wherein the ratio between the third area and the fourth area is equal to the ratio between the first area and the second area.

4. The semiconductor device according to claim 2, wherein the second area is at least two times and at most four times greater than the first area.

5. The semiconductor device according to claim 1, wherein the first bonding surface and the first metal layer are circular, and the second bonding surface and the second metal layer are elliptical.

6. The semiconductor device according to claim 1, wherein the first bonding surface and the first metal layer are circular, and the second bonding surface and the second metal layer are circular.

7. The semiconductor device according to claim 1, wherein the first metal layer and the second metal layer include:
a first layer in contact with the conductive member and contains Ni;
a second layer in contact with the first layer and contains Pd; and
a third layer in contact with the second layer and contains Au.

8. The semiconductor device according to claim 1, wherein the first electrode terminal and the second electrode terminal contain Cu.

9. The semiconductor device according to claim 1, further comprising:
a first bonding portion interposed between the first bonding surface and the first metal layer; and
a second bonding portion interposed between the second bonding surface and the second metal layer.

10. The semiconductor device according to claim 9, wherein the first bonding portion and the second bonding portion contain solder.

11. The semiconductor device according to claim 1, wherein the semiconductor element includes a plurality of third electrode terminals that are identical in shape to the first electrode terminal, and a plurality of fourth electrode terminals that are identical in shape to the second electrode terminal, and
the first electrode terminal and the plurality of third electrode terminals are disposed on the element obverse surface at a location on a first side in a first direction orthogonal to the thickness direction, and the second electrode terminal and the plurality of fourth electrode terminals are disposed on the element obverse surface at a location on a second side in the first direction.

12. The semiconductor device according to claim 1, wherein the conductive member includes a first lead, and
the first metal layer and the second metal layer are formed on the first lead.

13. The semiconductor device according to claim 1, wherein the conductive member includes a first lead and a second lead,
the first metal layer is formed on the second lead, and
the second metal layer is formed on the first lead.

14. The semiconductor device according to claim 1, further comprising an insulating substrate,
wherein the conductive member is a wiring formed on the insulating substrate.
